(19) United States
(12) Patent Application Publication
(10) Pub. No.: US 2003/0179123 A1
(43) Pub. Date: Sep. 25, 2003

(54) ANALOG-TO-DIGITAL CONVERSION USING A COUNTER

(76) Inventor: Alan D. DeVilbiss, Colorado Springs, CO (US)

Correspondence Address: HANES & SCHUTZ, P.C., 102 S. TEJON ST., SUITE 800, COLORADO SPRINGS, CO, 80903, US

(21) Appl. No.: 10/103,078

(22) Filed: Mar. 22, 2002

(51) Int. Cl. H03M 1/60; H03C 3/00

(52) U.S. Cl. 341/157; 327/101

(57) ABSTRACT

An analog-to-digital (A/D) converter converts an analog input signal to a digital representation. The A/D converter has a voltage controlled current source, a Schmidt trigger, a counter, a capacitor, and a transistor switch. The analog input voltage controls the voltage controlled current source. The negative terminal of the current source is coupled to ground, and the positive terminal is coupled to the capacitor, the transistor, and the input of the Schmidt trigger. The other terminal of the capacitor and the drain of the transistor are coupled to a power supply voltage source. The output of the Schmidt Trigger is coupled to the input of the counter. The Reset clock is coupled to the reset terminals of the Schmidt trigger and the counter. The output of the counter represents the digital equivalent of the analog input.

### FIELD OF THE INVENTION

The present invention relates to the field of analog and digital signals, and more particularly to analog-to-digital conversion.

### BACKGROUND OF THE INVENTION

Digital systems that process analog signals must convert analog inputs into a digital format. Analog-to-digital (A/D) converters are used for this purpose, receiving an analog voltage input and, in response, producing a corresponding digital output. A/D converters are used in many diverse applications such as communications, signal processing, computers, testing, radar, sonar, medical devices, and entertainment electronics.

Many different architectures and methods are known for analog-to-digital conversion. Choosing the A/D conversion technique to be used in a particular application usually depends on the considerations such as the speed, accuracy, cost, and power requirements of the application.

One conventional type of A/D converter is the parallel or flash converter. The flash converter senses every voltage level simultaneously by utilizing a plurality of comparators, each with its own voltage reference. These voltage references are usually generated by applying the full-scale voltage across a number of equal-valued resistors in series. Flash converters are very fast because the bits are determined in parallel, but they are generally limited to 6-10 bits of resolution due to the expense and power requirements of operating all the comparators simultaneously. Another problem associated with the large number of comparators is the heavy capacitive and resistive load on the analog input signal. A further problem is that the resistors are difficult to design with the necessary precision in the form of an integrated circuit and are susceptible to temperature variations.

A popular technique for A/D conversion that uses only one comparator is the successive approximation. Successive approximation utilizes a digital-to-analog (D/A) converter. The input of the D/A converter is set to a known digital value. The resulting output is compared with the captured analog input signal. The D/A inputs are then changed, starting with the most significant bit, until the analog output of the D/A matches the analog input. A variation of this method is the Ramp A/D converter whereby a counter chip counts up the input of the D/A converter, starting at 0. When the D/A converter output is higher than the analog input voltage, the counter is stopped. The counter is then reset for the next conversion. In yet another variation of this method, controls are added so that the counter can count up and down. These techniques require less circuitry than flash converters, and are common in PC applications because they can produce 16-110 bits of resolution relatively inexpensively.

Another conventional A/D conversion technique is known as single-slope integration. In single-slope integration, a counter is started at 0 while a capacitor is charged at a constant rate. The voltage is then periodically compared with the analog input voltage. When the voltage across the capacitor is equal to the analog input voltage, the counter is stopped. The value of the counter is now proportional to the input voltage.

A variation of this technique, called dual-slope integration, will produce more accurate results. In dual-slope integration, a current source proportional to the input voltage charges a capacitor. This capacitor is then discharged at a constant rate while a counter is started. When the capacitor has discharged to 0 v, the counter is stopped. This final count is now proportional to the analog input voltage. While these methods can be very accurate, they are relatively slow because as many comparisons to the analog input signal are required as there are analog levels to resolve.

In conventional A/D techniques, the analog input signal that is being converted should not change during the conversion. Accordingly, conventional A/D conversion techniques require that the analog input is sampled and captured at an instant of time. A switch transistor is momentarily turned on to charge a capacitor to the analog input voltage. This captured signal is then used to make the comparison. If the analog input signal was subjected to noise at the time of the capture, these techniques will result in significant error. Therefore, these techniques are susceptible to noise.

Further, according to the Nyquist sampling theorem, conventional A/D conversion techniques require that the sample rate is at least twice the frequency of the highest frequency component of the analog input signal. Frequency components exceeding this limit will typically result in aliasing, thereby creating a digital representation that will not faithfully reproduce the sampled signal. For this reason, conventional A/D converters generally require that the analog input signal pass through a low pass filter before it is digitized. Such filters are generally analog in nature, and are typically not compatible with low power technologies such as CMOS.

There are other A/D converter architectures, but the ones described represent the range of performance and cost found in today's converters. All these techniques require comparator circuits, which have inherent offsets that produce error. Comparator circuits generally have an undetermined state between the stable “0” and “1” when the inputs being compared are sufficiently close. Further, comparators generally require analog circuitry, which is difficult and expensive to incorporate in low power technologies such as CMOS. Further, these techniques can be sensitive to noise spikes on the analog input due to the sample and hold requirement.

### SUMMARY OF THE INVENTION

According to the principles of the present invention, an A/D converter converts an analog input signal to a digital representation. The A/D converter has a voltage controlled oscillator and a counter. The analog input signal controls the voltage controlled oscillator. The output of the voltage controlled oscillator is coupled to the input of the counter. The output of the counter represents the digital equivalent of the analog input.

According to further principals of the present invention, the voltage controlled oscillator includes a voltage controlled current source, a capacitor, a transistor, and a Schmidt trigger.

### DESCRIPTION OF THE DRAWINGS

FIG. 1 is a schematic circuit drawing illustrating one embodiment of the present invention.

FIG. 2 is a timing diagram of selected nodes in the schematic drawing presented in FIG. 1.

### DETAILED DESCRIPTION OF THE INVENTION

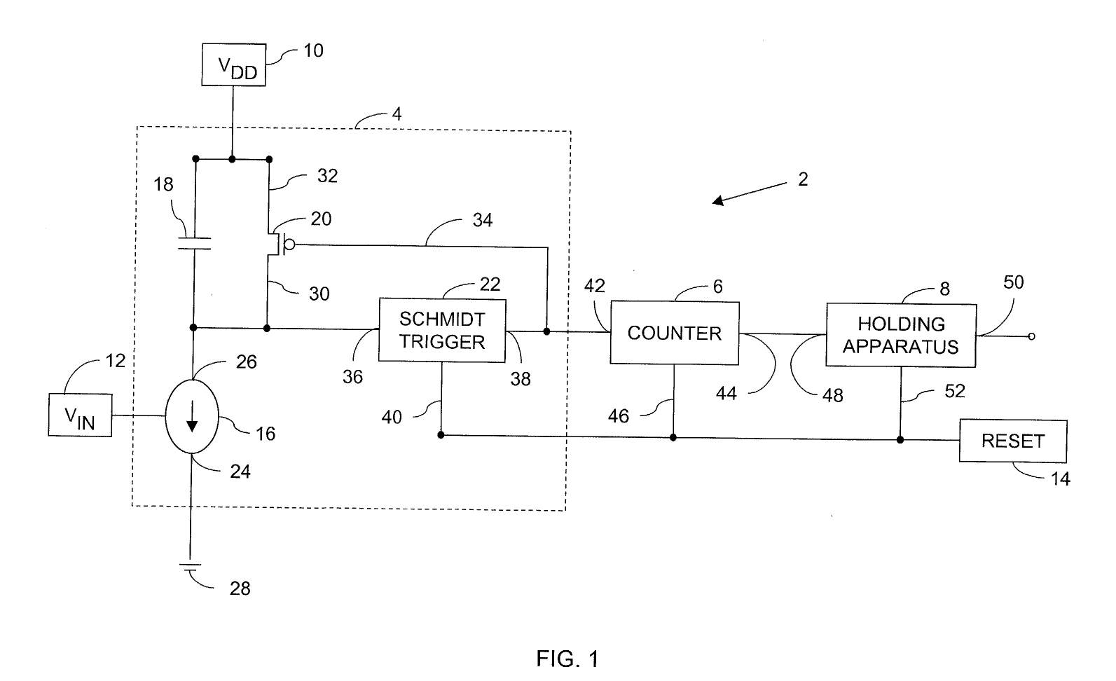

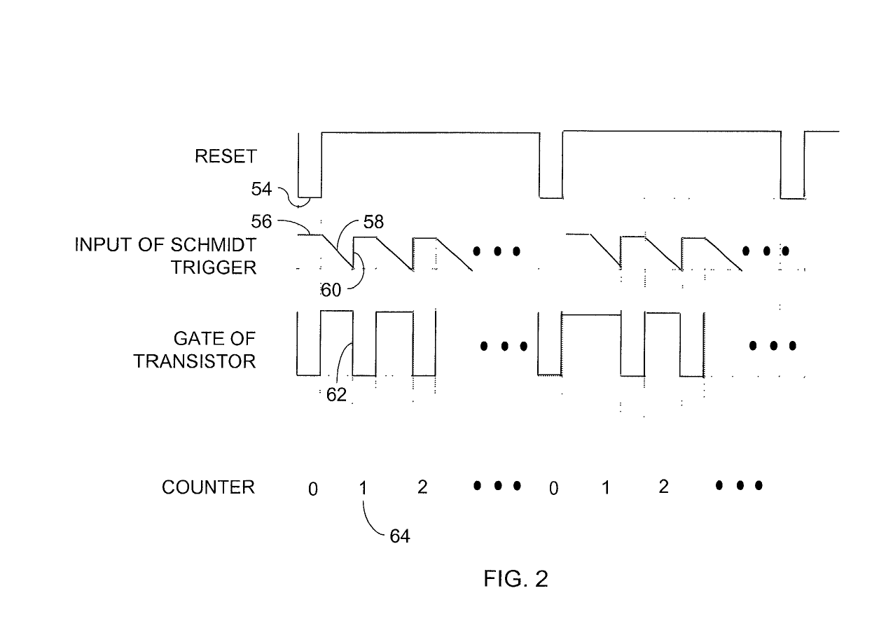

One embodiment of the present invention is described using the schematic diagram shown in FIG. 1 and the waveforms shown in FIG. 2. Referring now to FIG. 1, an analog-to-digital (A/D) converter 2 includes a voltage controlled oscillator (VCO) 4, a counter 6, and optionally, a holding apparatus 8. Supplied to A/D converter 2 are power supply voltage (Vdd) 10, analog input voltage (Vin) 12, and reset clock 14.

VCO 4 is any device or plurality of devices configured to generate an output having a signal frequency proportional to Vin 12. VCO 4 includes an input terminal and an output terminal. Vin 12 is applied to the input terminal. The output of VCO 4 is generated at the output terminal. In one embodiment, VCO 4 includes a voltage controlled current source 16, a capacitor 18, a transistor 20, and a Schmidt trigger 22. Although the VCO 4 is represented in terms of these components, various alternatives and modifications to VCO 4 can be devised by those skilled in the art without departing from the invention.

Voltage controlled current source 16 is any current source having an output current controllable to be proportional to Vin 12. In one embodiment, voltage controlled current source 16 has a negative terminal 24 and a positive terminal 26. The negative terminal 24 is coupled to ground 28.

Capacitor 18 is any device or apparatus acting as a capacitor for storing and releasing charge. Although capacitor 18 is represented in FIG. 1 as a single capacitor, capacitor 18 may be embodied by one or more than one capacitor or a combination of elements acting as a capacitor. In one embodiment, capacitor 18 is coupled between the positive terminal 26 of the voltage controlled current source 16 and Vdd 10.

Transistor 20 is any device or apparatus acting as an electronic or optical switch. Although transistor 20 is represented in FIG. 1 as a single transistor, transistor 20 may be embodied by one or more than one transistor or a combination of elements acting as a transistor. In one embodiment, transistor 20 is a MOSFET and has a source terminal 30, a drain terminal 32, and a gate terminal 34. Source terminal 30 is coupled to positive terminal 26 of voltage controlled current source 16. Drain terminal 32 is coupled to Vdd 10.

Schmidt trigger 22 is any device or plurality of devices configured to output either a high or a low logic state in response to an input and maintain the logic state until a threshold point is reached at the input. In one embodiment, Schmidt trigger 22 has an input terminal 36, an output terminal 38, and a reset terminal 40. Input terminal 36 is connected to positive terminal 26 of voltage controlled current source 16. Output terminal 38 is connected to gate 34 of transistor 20 and the output terminal of VCO 4. Reset terminal 40 is connected to reset clock 14.

In an alternative embodiment, capacitor 18 is coupled between one terminal of voltage controlled current source 16 and ground. Transistor 20 is an n-type transistor with drain terminal 32 coupled to ground 28 and source terminal 30 coupled to capacitor 18 and voltage controlled current source 16. The other terminal of voltage controlled current source 16 is coupled to Vdd 10.

Counter 6 is any device or apparatus acting as counter. Although counter 6 is represented in FIG. 1 as a single counter, counter 6 may be embodied by one or more than one counter or a combination of elements acting as a counter. In one embodiment, counter 6 has an input terminal 42, an output terminal 44, and a reset terminal 46. Input terminal 42 is coupled to output terminal 38 of Schmidt trigger 22. Reset terminal 46 is connected to reset clock 14. The digital output is generated at output terminal 44.

Holding apparatus 8 is any device or apparatus for holding a digital value. Examples of holding apparatus 8 include a flip-flop, a sample and hold circuit, a memory, and a latch. Holding apparatus 8 is represented in FIG. 1 as a single holding apparatus, holding apparatus 8 may be embodied by one or more than one holding apparatus 8 or a combination of elements acting as a holding apparatus. In one embodiment, holding apparatus 8 has an input terminal 48, an output terminal 50, and a reset terminal 52. Input terminal 48 is connected to output terminal 44 of counter 6. Reset terminal 52 is coupled to reset clock 14. The digital output from counter 6 is provided at output terminal 50 and held for one cycle of reset clock 14 so that it may be read.

In operation, when a pulse 54 from reset clock 14 goes low, Schmidt trigger 22 is triggered, resetting the output of counter 6 to 0. The output of Schmidt trigger 22 will turn on MOSFET 20, thereby shorting capacitor 18 and charging input terminal 36 of Schmidt trigger 22 to the power supply voltage Vdd. Markers 54 and 56 in FIG. 2 show the levels of reset clock 14 and input terminal 36 of Schmidt trigger 22 at that time point on a waveform diagram, respectively. When reset clock 14 returns to a high state, input terminal 36 of Schmidt trigger 22 is left floating at the power supply voltage Vdd.

Vin 12 is connected to voltage controlled current source 16. As the input voltage changes, the current drawn by current source 16 will change proportionally. Since the charge on capacitor 18 is floating, the current drawn will decrease the voltage on input terminal 36 of Schmidt trigger 22 as a function of time. This voltage decrease on input terminal 36 of Schmidt trigger 22 is marked on the waveform in FIG. 2 with the number 58. Note that the time scale on FIG. 2 is not to scale. The length of time that input terminal 36 of Schmidt trigger 22 stays at Vdd is very short compared to the entire cycle, and is exaggerated in FIG. 2 for purposes of illustration.

When input terminal 36 of Schmidt trigger 22 drops to a given voltage level threshold, Schmidt trigger 22 fires, causing the voltage on gate terminal 34 of transistor 20 to go to a low state, thereby again shorting capacitor 18 through MOSFET 20 and returning input terminal 36 of Schmidt trigger 22 to the power supply voltage Vdd. At the same time, Schmidt trigger output 38 will increment counter 6. The wave shapes of input terminal 36 of Schmidt trigger 22 and gate terminal 34 of transistor 20 at this time point are marked 60 and 62 in FIG. 2, respectively. Marker 64 in FIG. 2 represents the corresponding increment of counter 6. It should be noted that the time it takes for input terminal 36 of Schmidt trigger 22 to reach the trigger voltage of Schmidt trigger 22 is directly proportional to the voltage level of Vin 12.

Output 38 of Schmidt trigger 22 will now turn off MOSFET 20, leaving input terminal 36 of Schmidt trigger 22 floating at the power supply voltage Vdd 10 once again. This cycle the then repeats until the next low edge of pulse from reset clock 14, incrementing counter 6 every time Schmidt trigger 22 is triggered.

When reset clock 14 goes to a low state, the counter data is latched into holding apparatus 8, counter 6 is reset to 0, and Schmidt trigger 22 is triggered. Input terminal 38 of Schmidt trigger 22 is thereby charged to the power supply voltage Vdd. The count that is now latched in holding apparatus 8 represents data output 16, a digital representation of the Vin 12 during the time between the RESET pulses. The cycle described above then repeats.

As noted above, the time that it takes for the voltage on input terminal 38 of Schmidt trigger 22 to drop to the trigger voltage of Schmidt trigger 22 is directly proportional to the voltage level of the Vin 12. Since the time between pulses from reset clock 14 is fixed, it can be concluded that the final count before the next low edge of pulse from reset clock 14 is proportional to the Vin 12 as well. In this manner, Vin 12 is converted to a digital representation during the sample of time between the two low edges of a pulse from reset clock 14.

In an alternative embodiment, capacitor 18 is charged to a ground potential at the beginning of the cycle by utilizing an n-type transistor 20 with drain 32 coupled to ground 28, source 30 coupled to capacitor 18 and to one terminal of a voltage controlled current source 16, the other terminal of the current source 16 connected to Vdd 10. In this embodiment, capacitor 18 is charged to a more positive voltage than the trigger voltage of Schmidt trigger 22. All other operations are identical to what has been described above.

The present invention discloses an A/D converter that integrates the analog input signal over time, thereby substantially reducing susceptibility to noise. The invention does not use a comparator circuit, making it straightforward for those skilled in the art to incorporate this invention into low power CMOS integrated circuit technologies. Further, this invention does not utilize a voltage reference, which generally consumes power and requires an accuracy that is difficult to achieve in low power integrated circuit processes. Further, the present invention does not require a low pass filter, which typically requires analog circuits that are typically incompatible with low power CMOS technologies as well. The invention described herein, is, therefore, well suited for low power applications such as portable battery systems and RFID tags.

The foregoing description is only illustrative of the invention. Various alternatives and modifications can be devised by those skilled in the art without departing from the invention. In particular, wherever a device is connect or coupled to another device, additional devices may be present between the two connected devices. Accordingly, the present invention embraces all such alternatives, modifications, and variances that fall within the scope of the appended claims.

What is claimed is:

1. An analog-to-digital (A/D) converter for converting an analog input voltage to a digital output, the A/D converter supplied with a power supply voltage source and a reset clock, the A/D converter comprising:
(a) a voltage controlled oscillator (VCO) having an input terminal and an output terminal, the analog input voltage applied to the input terminal, a signal frequency generated at the output terminal proportional to the analog input voltage applied to the input terminal; and
(b) a counter having an input terminal, an output terminal, and a reset terminal, the input terminal coupled to the output terminal of the VCO and the reset terminal connected to the reset clock, the digital output generated at the output terminal.

2. The A/D converter of claim 1 wherein the VCO includes:
(a) a voltage controlled current source having a negative terminal, a positive terminal, and a current output proportional to the analog input voltage source, the negative terminal coupled to ground;
(b) a capacitor coupled between the positive terminal of the voltage controlled current source and the power supply voltage source;
(c) a transistor having a source terminal, a drain terminal, and a gate terminal, the source terminal coupled to the positive terminal of the current source and the drain terminal coupled to the power supply voltage source; and
(d) a Schmidt trigger having an input terminal, an output terminal, and a reset terminal, the input terminal connected to the positive terminal of the voltage controlled current source, the output terminal connected to the gate of the transistor and the output terminal of the VCO, and the reset terminal connected to the reset clock.

3. The A/D converter of claim 1 wherein the VCO includes:
(a) a Schmidt trigger having an input terminal, an output terminal, and a reset terminal, the output terminal coupled to the input terminal of the counter and the output terminal of the VCO, the reset terminal connected to the reset clock;
(b) a voltage controlled current source having a negative terminal, a positive terminal, and a current output proportional to the analog input voltage source, the negative terminal coupled to ground, the positive terminal connected to the input terminal of the Schmidt trigger;
(c) a transistor having a source terminal, a drain terminal, and a gate terminal, the source terminal coupled to the positive terminal of the current source and the drain terminal coupled to the power supply voltage source, the gate terminal connected to the output terminal of the Schmidt trigger; and
(d) a capacitor coupled between the positive terminal of the voltage controlled current source and the power supply voltage source.

4. The A/D converter of claim 1 wherein the VCO includes:
(a) a voltage controlled current source having a negative terminal, a positive terminal, and a current output proportional to the analog input voltage source, the positive terminal coupled to the power supply voltage;
(b) a capacitor coupled between the negative terminal of the voltage controlled current source and ground;
(c) a transistor having a source terminal, a drain terminal, and a gate terminal, the drain terminal coupled to the negative terminal of the current source and the source terminal coupled to ground; and
(d) a Schmidt trigger having an input terminal, an output terminal, and a reset terminal, the input terminal connected to the negative terminal of the voltage controlled current source, the output terminal connected to the gate of the transistor and the output terminal of the VCO, and the reset terminal connected to the reset clock.

5. The A/D converter of claim 1 further including a holding apparatus having an input terminal, an output terminal, and a reset terminal, the input terminal connected to the output terminal of the counter and the reset terminal coupled to the reset clock, the digital output provided at the output terminal.

6. The A/D converter of claim 5 wherein the holding apparatus is selected from the group consisting of a flip-flop, a sample and hold circuit, a memory, and a latch.

7. A method for converting an analog input voltage to a digital output, the method comprising:
(a) starting a timer;
(b) discharging a capacitor and resetting a counter;
(c) generating a current proportional to the analog input voltage;
(d) applying the current to charge the capacitor, creating a voltage difference across the capacitor;
(e) sensing the voltage at the capacitor;
(f) discharging the capacitor and incrementing the counter when the voltage of the capacitor reaches a threshold value;
(g) repeating steps d through f until the timer expires; and
(h) generating the digital output from the counter.

8. The method of claim 7 wherein discharging the capacitor includes opening the gate of a transistor to supply a voltage to each terminal of the capacitor.

9. The method of claim 8 further including closing the gate of the transistor to remove the voltage from at least one terminal of the capacitor.

10. The method of claim 7 wherein sensing the voltage at the capacitor includes applying the voltage at one terminal of the capacitor to a Schmidt trigger.

11. The method of claim 10 wherein discharging the capacitor when the voltage of the capacitor reaches a threshold value includes the Schmidt trigger outputting a low voltage to the gate of the transistor.
